(19) United States
(12) Patent Application Publication
(10) Pub. No.: US 2005/0012116 A1
(43) Pub. Date: Jan. 20, 2005

(54) Method for a first semiconductor device to determine if it is coupled to a second semiconductor device

(76) Inventors: Swee Hock Lim, Singapore (SG); Yean Kee Yong, Singapore (SG)

Correspondence Address: SENNIGER POWERS LEAVITT AND ROEDEL, ONE METROPOLITAN SQUARE, 16TH FLOOR, ST LOUIS, MO, 63102, US

(21) Appl. No.: 10/474,404

(22) PCT Filed: Feb. 19, 2002
(86) PCT No.: PCT/SG02/00024

(51) Int. Cl. H01L 31/072

(52) U.S. Cl. 257/199

(57) ABSTRACT

A method for a first semiconductor device (1) coupled to a non-floating bus (3) to determine whether a second semiconductor device (2) is also coupled to the non-floating bus (3). The first semiconductor device (1) sends a control signal for the second semiconductor device (2) to the non-floating bus (3), and the first semiconductor device waits for a response signal from the non-floating bus (3). The first semiconductor device (1) determines that the second semiconductor device (2) is coupled to the non-floating bus (3) if a response signal is received, and determines that the second semiconductor device (2) is not connected to the non-floating bus (3) if a response signal is not received.

The invention relates to a method for a first semiconductor device to determine if it is coupled to a second semiconductor device.

When a master semiconductor chip, such as processor chip or a control chip, is switched on, it is common for the master chip to have to determine whether another chip, such as a slave chip, for example, an electrically erasable programmably read only memory (EEPROM) chip is coupled to it. Conventionally, this problem has been solved by tying an external pin on the master chip to a defined state. For example, state “1” may define that the slave chip is coupled to the master chip and state “0” may define that the slave chip is not connected to the master chip. Therefore, when the master chip starts up, it will proceed to communicate with the slave chip if it detects that the external pin is tied to 1 or communication with the slave chip will go to a dormant state if the pin is tied to 0.

However, this conventional solution has the disadvantage of increasing the pin count on the master chip by requiring a pin specifically to indicate whether the slave chip is connected to the master chip. In addition, this solution requires the presence of a manual switch or pull-up resistor on the board itself to switch or pull up the pin to the state “1” if the slave chip is connected to the master chip. It also requires manual intervention to indicate whether the slave chip is connected to the master chip as it is necessary for the pin to be manually set to indicate whether the slave chip is connected to the master chip. Therefore, the conventional solution to this problem also has the disadvantage of the possibility of human error.

In accordance with the present invention, there is provided a method for a first semiconductor device coupled to a non-floating bus to determine whether a second semiconductor device is also coupled to the non-floating bus, the method comprising the first semiconductor device sending a control signal for the second semiconductor device to the non-floating bus, and the first semiconductor device waiting for a response signal from the non-floating bus, the first semiconductor device determining that the second semiconductor device is coupled to the non-floating bus if a response signal is received and determining that the second semiconductor device is not connected to the non-floating bus if a response signal is not received.

The invention has the advantage of enabling a master chip to detect whether a slave chip is coupled to it without requiring an external pin to be tied to a predefined state.

Preferably, if the first semiconductor device does not receive a response signal, the first semiconductor device resends the control signal for the second semiconductor device to the non-floating bus after a time interval. Preferably, the time interval is a predetermined time interval.

Typically, the first semiconductor device resends the control signal a predetermined number of times and if a response signal is not received after the control signal has been sent the predetermined number of times, the first semiconductor device determines that the second semiconductor device is not coupled to the non-floating bus.

Preferably, the control signal comprises a control pattern for the second semiconductor device.

Preferably, the response signal, which the first semiconductor device waits for, is a predetermined response signal.

Typically, the first semiconductor device is a master chip, such as a processor chip or a control chip, and may be for example a network switch chip.

Typically, the second semiconductor device is a slave chip, such as a memory chip, and may be for example an EEPROM chip.

Preferably, the non-floating bus is a non-floating serial bus, and may be, for example, an IIC serial bus.

An example of a method for a first semiconductor device to determine whether a second semiconductor device is coupled to it in accordance with the invention will now be described with reference to the accompanying drawing, in which:

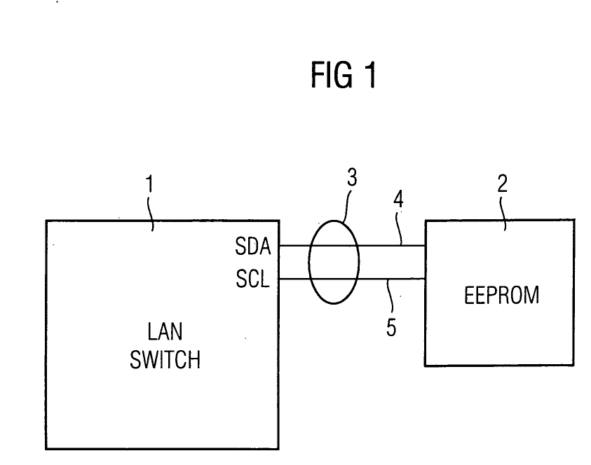

FIG. 1 is a block diagram showing a local area network (LAN) switch chip coupled to an EEPROM chip.

FIG. 1 shows a LAN switch chip 1 which is coupled to an EEPROM chip 2 via an IIC (I²C) serial interface bus 3. The I²C bus 3 comprises data address line 4 and a clock line 5.

When the LAN switch chip 1 is switched on, the LAN switch chip 1 needs to determine whether the EEPROM 2 is coupled to it via the I²C bus 3.

Accordingly, when the LAN switch chip 1 is switched on, the chip 1 assumes that the EEPROM 2 is coupled to it via the I²C bus 3 and proceeds to send a controlled pattern for the EEPROM chip 2 onto the IIC data line 4 and controls the clock for the IIC clock line 5. After sending the control pattern, the chip 1 waits for an acknowledge signal from the EEPROM chip 2.

If an acknowledge signal from the EEPROM chip 2 is received, the chip 1 determines that the EEPROM chip 2 is coupled to it via the I²C bus 3 and proceeds to set the starting address for the EEPROM chip 2.

However, if the chip 1 does not receive an acknowledge signal from the EEPROM chip 2, the chip 1 stops the current operation and sends a stop signal to the I²C bus 3. The chip 1 then waits for a predetermined period of time before proceeding to retry accessing the EEPROM chip 2 by resending the control pattern for the EEPROM chip to the I²C data line 4. Typically, the chip 1 tries resending the control pattern up to three times. If no acknowledge signal is received from the EEPROM 2 after the control pattern is sent the third time, the chip 1 determines that the EEPROM 2 is not coupled to the I²C bus 3.

Although in the example described above, the chip 1 uses an I²C serial interface bus, the invention could be used with any non-floating bus.

The invention has the advantage that the master chip (first semiconductor device) determines whether the slave chip (the second semiconductor device) is coupled to it by automatically attempting to send the control pattern for the slave chip to the slave chip, and determining that the slave chip is not coupled to it if a response signal is not received from the slave chip. Hence, this has the advantage of not requiring an external pin of the chip 1 to be tied to a specified state to enable the master chip to determine whether the slave chip is connected to it.

1. A method for a first semiconductor device coupled to a non-floating bus to determine whither a second semiconductor device is also coupled to the non-floating bus, the method comprising the first semiconductor device sending a control signal for the second semiconductor device to the non-floating bus, and the first semiconductor device waiting for a response signal from the non-floating bus, the first semiconductor device determining that the second semiconductor device is coupled to the non-floating bus if a response signal is received and determining that the second semiconductor device is not connected to th non-floating bus if a response signal is not received.

2. A method according to claim 1, wherein if the first semiconductor device does not receive a response signal, the first semiconductor device resends the control signal pattern for the second semiconductor device to the non-floating bus after a time interval.

3. A method according to claim 2, wherein the time interval is a predetermined time interval.

4. A method according to claim 2, wherein the first semiconductor device resends the control signal a predetermined number of times and if no response signal is received after the control signal has been sent the predetermined number of times, the first semiconductor device determines that the second semiconductor device is not coupled to the non-floating bus.

5. A method according to claim 1, wherein the control signal comprises a control pattern for the second semiconductor device.

6. A method according to claim 1, wherein the first semiconductor device waits for a predetermined response signal.

7. A method according to claim 1, wherein the first semiconductor device is a master chip.

8. A method according to claim 1, wherein the second semiconductor device is a slave chip.

9. A method according to claim 1, wherein the non-floating bus is a non-floating serial bus.

10. A method according to claim 9 wherein the non-floating serial bus is an IIC serial bus.
